(19) United States
(12) Patent Application Publication
(10) Pub. No.: US 2025/0385105 A1
(43) Pub. Date: Dec. 18, 2025

(54) COVER FOR A CLEANING MODULE FOR CLEANING A SEMICONDUCTOR WAFER, AND METHOD FOR CLEANING A SEMICONDUCTOR WAFER IN A CLEANING LINE

(71) Applicant: Siltronic AG, Munich (DE)

(72) Inventors: Bertram MÖCKEL, Freiberg (DE); Simon ROTHENAICHER, Erlbach (DE); Günter SCHWAB, Neuötting (DE)

(21) Appl. No.: 18/878,089

(22) PCT Filed: Jun. 14, 2023
(86) PCT No.: PCT/EP2023/065899

§ 371 Date: Dec. 23, 2024

(30) Foreign Application Priority Data
Jun. 27, 2022 (EP) 22181251.4

(51) Int. Cl. H01L 21/67; H01L 21/677; H01L 21/683

(52) U.S. Cl. CPC H01L 21/6704; H01L 21/67751; H01L 21/683

(57) ABSTRACT

A cover is used for a cleaning module, in which a semiconductor wafer is cleaned with a fluid in a vertically orientated state. The cover includes: a base having a wedge-like cross section; a sealing frame for the cover; a hood covering the base and having a slot for introducing the semiconductor wafer into the cleaning module; a panel displaceable over the base and over the slot; and a bracket secured to the hood so as to be displaceable over the slot. A first drainage channel is incorporated in an upper side face of the bracket parallel with the slot and along an edge border, which is close to the slot, of the bracket. A second drainage channel is incorporated in an upper side face of the panel parallel with the slot and along an edge border, which is close to the slot, of the panel.

### CROSS REFERENCE TO RELATED APPLICATIONS

This application is a U.S. National Phase application under 35 U.S.C. § 371 of International Application No. PCT/EP2023/065899, filed on Jun. 14, 2023, and claims benefit to European Patent Application No. EP 22181251.4, filed on Jun. 27, 2022. The International Application was published in German on Jan. 4, 2024 as WO 2024/002690 A1 under PCT Article 21(2).

### FIELD

The present disclosure relates to a cover for a cleaning module for cleaning a semiconductor wafer in which the semiconductor wafer is processed with a fluid in a vertically orientated state during a cleaning step. The present disclosure also relates to a method for cleaning a semiconductor wafer in a cleaning line, which comprises at least one cleaning module with such a cover.

### BACKGROUND

US 2006 0 254 715 A1 describes a method by means of which a semiconductor wafer is transported between cleaning modules of a cleaning line which are arranged one after the other in order to subject them to a single wafer cleaning operation in each of the cleaning modules. During this, at least one robot is moved along a guide to one of the cleaning modules and a manipulator is lowered into the cleaning module in order to deposit or receive the semiconductor wafer in the cleaning module. The disadvantage here is that fluid which drips from the manipulator or the semiconductor wafer can reach the cleaning module and can put the success of the cleaning process at risk.

According to US 2014/0209239 A1, a cleaning module with a closable cover may be provided. In the open state, the cover is intended to ensure access to the cleaning module and in the closed state it is intended to prevent fluid from the cleaning module from being sprayed into the environment during the cleaning of a semiconductor wafer.

### SUMMARY

In an embodiment, the present disclosure provides a cover that is used for a cleaning module, which is configured for cleaning a semiconductor wafer and in which the semiconductor wafer is configured to be processed with a fluid in a vertically orientated state during a cleaning step. The cover includes: a base having a wedge-like cross section; a sealing frame configured for placing the cover on the cleaning module; a hood, which covers the base and which has a slot configured for introducing the semiconductor wafer into the cleaning module; a panel, which is displaceable over the base and over the slot; and a bracket, which is secured to the hood so as to be displaceable over the slot. A first drainage channel is incorporated in an upper side face of the bracket parallel with the slot and along an edge border, which is close to the slot, of the bracket. A second drainage channel is incorporated in an upper side face of the panel parallel with the slot and along an edge border, which is close to the slot, of the panel.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a perspective view of a cover according to the present disclosure;

FIG. 2 shows a side view of the cover; and

FIG. 3 shows a plan view of the cover.

### DETAILED DESCRIPTION

Aspects of the present disclosure are directed to limiting fluid from being able to unintentionally reach cleaning modules for cleaning a semiconductor wafer.

According to an aspect of the present disclosure a cover is provided for a cleaning module for cleaning a semiconductor wafer, in which the semiconductor wafer is processed with a fluid in a vertically orientated state during a cleaning step. The cover includes a base member having a wedge-like cross section, a sealing frame for placing the cover on the cleaning module, a hood which covers the base member and which has a slot for introducing the semiconductor wafer into the cleaning module and a bracket which is secured to the hood so as to be able to be displaced over the slot. A first drainage channel is incorporated in an upper side face of the bracket parallel with the slot and along an edge border, which is close to the slot, of the bracket. A panel, which can be displaced over the base member and over the slot, is also included. A second drainage channel is incorporated in an upper side face of the panel parallel with the slot and along an edge border, which is close to the slot, of the panel.

The panel which can be displaced over the slot of the hood and the bracket are used to reduce the width of the slot to the greatest possible extent when the slot is open. Drops which can fall through the slot into the cleaning module are prevented if they strike the bracket or the panel. Drops which fall on the bracket or the panel are discharged by means of the first drainage channel on the upper side face of the bracket or the second drainage channel on the upper side face of the panel outward away from the cleaning module.

The present disclosure also relates to a method for cleaning a semiconductor wafer in a cleaning line, which comprises at least one cleaning module in which a vertically orientated semiconductor wafer is processed during a cleaning step with a fluid of the cleaning step, wherein a gripping system for pick up or put down the semiconductor wafer is moved through a slot of a hood of a cover of the cleaning module into the cleaning module. The method is characterized in that the cleaning module is provided with a cover according to an aspect of the present disclosure, and the bracket and the panel are pushed against each other so that, when pick up or put down a semiconductor wafer using a gripping system, the width of the slot is limited to an extent which is necessary for movements of the gripping system. Preferably, it is ensured that for such movements toward the bracket or the panel an additional play of no more than 2 mm is provided.

Preferably, the method is used in a cleaning line which comprises two or more cleaning modules which are each provided with a cover according to an aspect of the present disclosure.

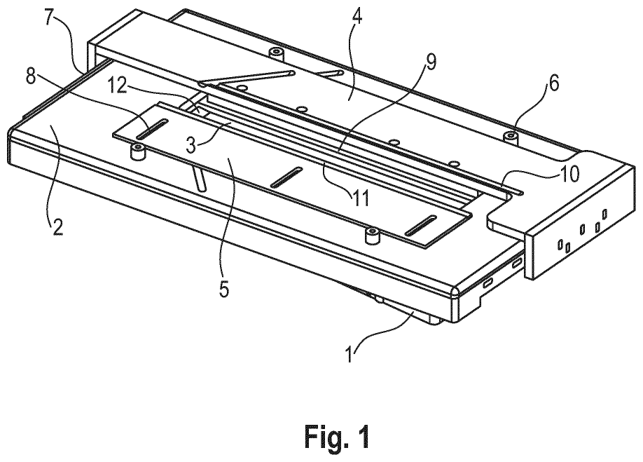

The cover shown in FIG. 1 comprises a base member 1, a sealing frame 12, a hood 2 having a slot 3, a bracket 4 and a panel 5. The base member (base) 1 has a wedge-like cross section and is positioned by means of the sealing frame 12 on a cleaning module which is not illustrated. The hood 2 having a slot 3 for introducing the semiconductor wafer into the cleaning module by means of a gripping system is fixed to the base member 1 by means of sleeves 6 of the base member 1 and covers it. In the open state of the cover illustrated, the slot 3 flanks a bracket 4 at one side of the slot 3 and a panel 5 at the opposite side of the slot 3. The bracket 4 is secured to a guide rail 7 of the hood 2 so as to be able to be displaced over the slot 3. The bracket 4 can be displaced so far in the direction of the slot 3 that it completely covers it and thus moves the cover into a closed state. The panel 5 at the other side of the slot 3 has elongate holes 8 along which it can be pushed via the slot 3 in order in the open state of the cover to be able to adjust the width of the slot 3. Below the hood 2, there is arranged an impact bar 9 which is secured to the lower side of the bracket 4. The slot 3 is in the open state of the cover flanked by drainage channels 10, 11. The drainage channel 10 is incorporated into the upper side face of the bracket 4 close to the edge border of the bracket 4 adjacent to the slot 3 and is orientated parallel with the slot 3. The drainage channel 11 is incorporated into the upper side face of the panel 5 close to the edge border of the panel adjacent to the slot 3 and is orientated parallel with the slot 3.

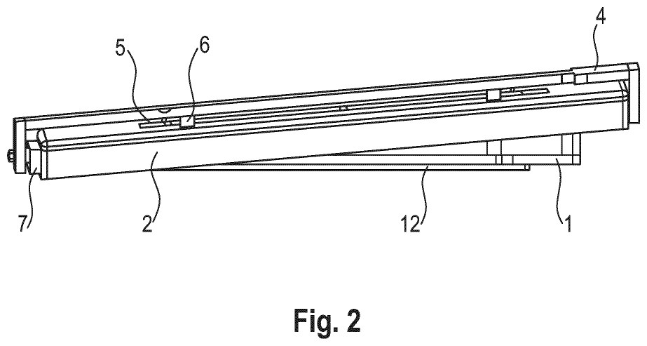

FIG. 2 shows a side view of the cover. As a result of the wedge-like cross section of the base member 1, there is a descending gradient toward the guide rail 7. The bracket 4 and the panel 5 are inclined in accordance with this descending gradient so that drops of a fluid which fall onto the bracket 4 or the panel 5 are discharged along the drainage channel 10 or drainage channel 11 and are consequently prevented from falling through the slot 3 into the cleaning module.

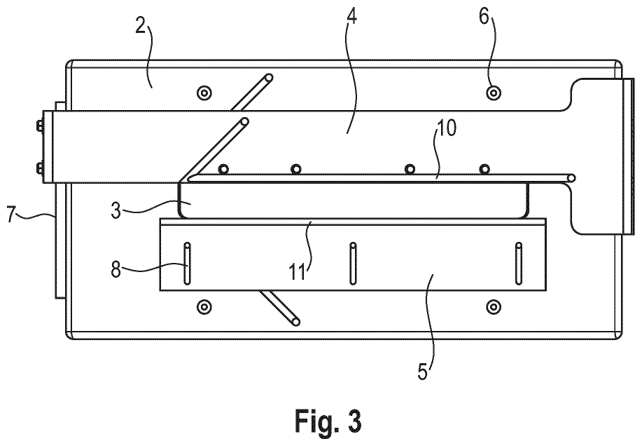

FIG. 3 shows a top view of the cover in the open state. The width of the slot is dependent on the length of the displacement path along which the bracket 4 and the panel 5 have been pushed over the slot. The bracket 4 and the panel 5 are pushed against each other so that, when the semiconductor wafer is deposited or received by the gripping system, the width of the slot is limited to a dimension which is required for movements of the gripping system.

The possibility of fluid unintentionally being able to reach the cleaning module through the slot when the cover is in the open state is effectively limited by this adjustment of the width of the slot.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS USED

1 Base member
2 Hood
3 Slot
4 Bracket
5 Panel
6 Sleeve
7 Guide rail
8 Elongate hole
9 Impact bar
10 Drainage channel
11 Drainage channel
12 Sealing frame

1. A cover for a cleaning module, the cleaning module being configured for cleaning a semiconductor wafer and in which the semiconductor wafer is configured to be processed with a fluid in a vertically orientated state during a cleaning step, the cover comprising:
a base having a wedge-like cross section;
a sealing frame configured for placing the cover on the cleaning module;
a hood, which covers the base and which has a slot configured for introducing the semiconductor wafer into the cleaning module;
a panel, which is displaceable over the base and over the slot; and
a bracket, which is secured to the hood so as to be displaceable over the slot,
wherein a first drainage channel is incorporated in an upper side face of the bracket parallel with the slot and along an edge border, which is close to the slot, of the bracket, and
wherein a second drainage channel is incorporated in an upper side face of the panel parallel with the slot and along an edge border, which is close to the slot, of the panel.

2. A method for cleaning a semiconductor wafer in a cleaning line which comprises at least one cleaning module, the method comprising:
processing the semiconductor wafer, in a vertical orientation in the at least one cleaning module, during a cleaning step, with a fluid;
using a gripping system, which is configured for picking up or putting down the semiconductor wafer, moving the semiconductor wafer through a slot of a hood of a cover of the cleaning module into the cleaning module, the cleaning module being provided with the cover as claimed in claim 1, and wherein the bracket and the panel are pushed against each other so that, during the picking up or putting down of the semiconductor wafer using the gripping system, the width of the slot is limited to an extent which is necessary for movements of the gripping system.

3. The method as claimed in claim 2, wherein it is ensured that, for the movements of the gripping system toward the bracket or the panel, an additional play of no more than 2 mm is provided.

4. The method as claimed in claim 2, wherein the cleaning line comprises two or more cleaning modules which are each provided with a respective cover.
